(19) United States
(12) Patent Application Publication
(10) Pub. No.: US 2021/0182145 A1
(43) Pub. Date: Jun. 17, 2021

(54) ELECTRONIC SYSTEM COMPRISING A DEVICE FOR ESTIMATING FAULTS OF AN ELECTRONIC MEMORY SUBJECTED TO HIGH-ALTITUDE FLIGHT CONDITIONS

(71) Applicant: THALES, Courbevoie (FR)

(72) Inventors: Patrick DERVIN, Merignac (FR); Frédéric CAUDOUX, Merignac (FR); Jean MURZEAU, Merignac (FR)

(21) Appl. No.: 17/247,351

(22) Filed: Dec. 8, 2020

(30) Foreign Application Priority Data
Dec. 17, 2019 (FR) 1914561

(51) Int. Cl. G06F 11/10

(52) U.S. Cl. CPC G06F 11/1004

(57) ABSTRACT

An electronic system for aeronautical applications, includes at least one electronic memory comprising a first plurality (T) of words and an error detection system for detecting errors in the words. The electronic system comprises an error counting device comprising: a register comprising a second plurality (NBR) of bits, an address of a bit being associated with at least one word; means for indexing the bit associated with the word when the error detection system flags an alteration of the word, the indexation of the bit being unique within a given time period, regardless of the number of times the alteration of the word is detected by the error detection system within this given time period; means for resetting the register at the end of the given time period.

### CROSS-REFERENCE TO RELATED APPLICATIONS

This application claims priority to foreign French patent application No. FR 1914561, filed on Dec. 17, 2019, the disclosure of which is incorporated by reference in its entirety.

### FIELD OF THE INVENTION

The invention lies within the technical field of electronic memories embedded on aircraft. When an aircraft is moving at high altitude, typically 10 000 metres and above, the electronic equipment and, in particular the electronic memories, are exposed to high-energy particles, typically neutrons, that can affect the operation of the primary electronic components. When the effect is sufficient to cause a change of state of the component, it is called “single effect upset” or “SEU”, or “multiple effect upset” or “MEU”. Thus, an electronic “0” can be converted into an electronic “1” and vice versa.

### BACKGROUND

More specifically, the technical field of the invention is that of the volatile memories of “RAM”, RAM being the acronym for “random access memory”, and their derivatives, and of the non-volatile memories of “ROM”, ROM being the acronym for “read only memory”.

It is understood that this problem of alteration of the memories is extremely sensitive insofar as the avionics equipment is critical to ensuring the safety of the aircraft and of its passengers. Such equipment is, consequently, subject to extremely stringent certification demands.

Moreover, the trend in electronic technologies allows an increasingly significant miniaturization of the components and, consequently, makes them more sensitive to such disturbances.

It is therefore important to know the number of cells or words of a memory which are affected by an SEU or an MEU over a given period in real conditions of use. This ratio is known as “FIT rate”, which stands for “Failure In Time rate”, or rate of failures per unit of time. It is important to know this rate when the memory is in a computer and in real conditions of use in the aeroplane. This characterization is different from that performed by the manufacturer in laboratory conditions.

To determine this rate, there are two possible approaches. In the first approach, the entire memory is exhaustively scanned to detect alterations and count them. This first approach gives an accurate result but the impact on performance is very high because the detection is intrusive. The accesses dedicated to detection are added to the operational accesses, thus reducing the useful bandwidth of the memory or necessitating more complex electronics such as, for example, a dual-port memory, a solution which is possible only for memories of small size. This drawback is generally prohibitive.

In the second approach, the alterations are detected and counted only during operational reads of the memory. This second approach is much simpler to implement than the first but it presents two main drawbacks:
the exhaustive scanning of the memory is not guaranteed during the observation period;
there is a risk of counting a same alteration several times when the operational accesses read the same memory cell several times during the observation period, which is an extremely common situation, thus falsifying the measurements.

To correct the second drawback, some integrated circuits, such as the “FPGA” circuits, FPGA being the acronym for “field-programmable gate arrays”, or the “ASIC” circuits, ASIC being the acronym for “application-specific integrated circuit”, correct the content of the memory when the alteration is detected, which guarantees that it is counted only once. However, these memory correction devices are highly complex and have an impact on performance because the correction device blocks the readout flow during the time needed to rewrite the corrected datum.

Consequently, the existing solutions are either too intensive in terms of execution time or partially erroneous.

### SUMMARY OF THE INVENTION

One object of the invention is to remedy the problem of counting one and the same alteration several times when the operational accesses read the same memory cell several times during the observation period, without altering reading times and without making substantial modifications to the electronic systems being monitored.

More specifically, the electronic system for aeronautical applications according to the invention comprises at least one electronic memory comprising a first plurality of words and a system for detecting errors of said words, characterized in that the electronic system comprises an error counting device comprising:
a register comprising a second plurality of bits, an address of a bit being associated with at least one word;
means for indexing the bit associated with said word when the error detection system flags an alteration of said word, the indexing of said bit being unique within a given time period, regardless of the number of times the alteration of said word is detected by the error detection system within said given time period;
means for resetting the register at the end of the given time period.

Advantageously, the second plurality is equal to the first plurality, the number of bits of the register being strictly equal to the number of words of the memory, each address corresponding to a single word.

Advantageously, the second plurality is a submultiple of the first plurality, the words being divided up by groups of the same size, each group of words being associated with a unique bit address.

Advantageously, the different words of one and the same group associated with a unique bit address have address numbers which follow one another.

Advantageously, the different words of one and the same group associated with a unique bit address are chosen so as to be physically separated in the electronic memory.

### BRIEF DESCRIPTION OF THE DRAWINGS

Other features, details and advantages of the invention will become apparent on reading the description given with reference to the attached drawings which are given by way of example and which represent, respectively:

FIG. 1 an illustration of the electronic system according to the invention;

FIG. 2 an illustration of a first mode of operation of the system according to the invention;

FIG. 3 an illustration of a second mode of operation of the system according to the invention.

### DETAILED DESCRIPTION

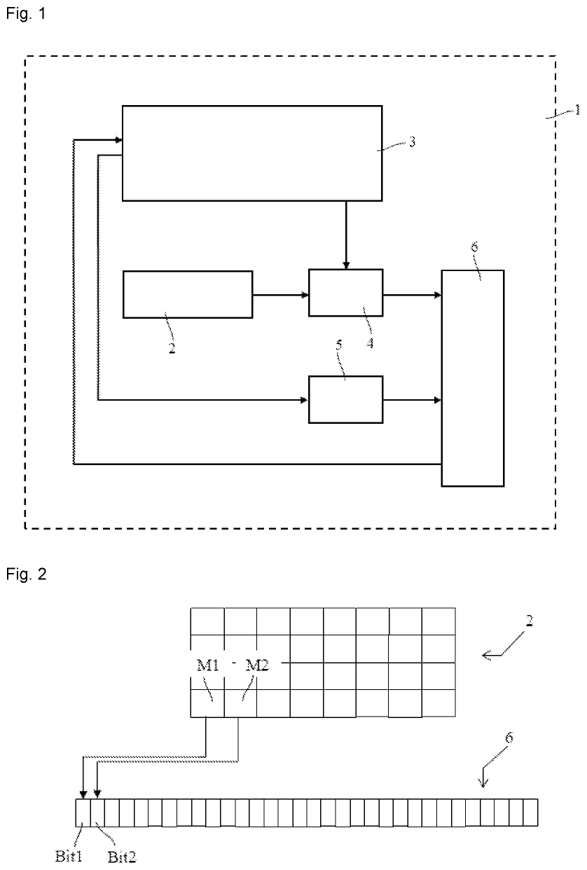

As an example, FIG. 1 represents an embedded electronic system 1 for aeronautical applications according to the invention. This system can be of any kind. In this figure, only the elements essential to the operation of the device for estimating and counting faults of the electronic memory have been represented. The arrows indicate the relationships between the different elements. The electronic system is notably an electronic computer embedded on an aircraft.

The electronic system 1 comprises at least one electronic memory 2. The device according to the invention operates with all kinds of memory. The system is suited to the electronic memories that are likely to be sensitive to the high-energy cosmic particles or radiations present at altitudes above or equal to 10 000 metres.

As an example, this memory can be a RAM or a ROM or any type of memory sensitive to high-altitude radiations. Hereinbelow, T denotes the number of words contained in the memory 2.

Generally, the size of the memories is a power of 2. Nevertheless, the device operates equally well with a memory size which is not a power of 2. The memory is conventionally addressed by a data bus.

The electronic system 1 comprises a device for counting errors of said memory. This counting device comprises different elements detailed hereinbelow.

An electronic processor 3. It manages all of the means allowing the number of words of the electronic memory 2 which include an error to be determined. This processor can be independent or be a dedicated function managed by an electronic computer comprising other applications. The processor can possibly also be an HW state machine or hardwired sequencer.

An error estimator 4, also known by the term “EDC”, meaning “error detection code”. There are different techniques that allow errors to be detected in a binary-coded word. They are all based on the addition of redundant information. In the event of an error in the word, the redundancy is designed for that error to result in an inconsistency in certain parameters and thus for the error to be detected. Generally, these systems are designed to allow not only the detection, but also the correction, of the errors detected.

A register 6 comprising a number NBR of bits. This register can be reset by the device 5. This reset can be done by software or by an electronic state machine. The device according to the invention can be adapted to all kinds of memory size. It is however necessary to adapt the size of the register which is linked to it as a function of the size of the memory.

Ideally, the number NBR is equal to that of the memory size T. Each bit of the register is then associated with one, and only one, word of the memory. FIG. 2 illustrates this principle. The memory 2 comprises 32 words and the register 6 comprises 32 bits. Thus, the first word M1 is associated with the bit 1, the next word M2 with the bit 2 and so on.

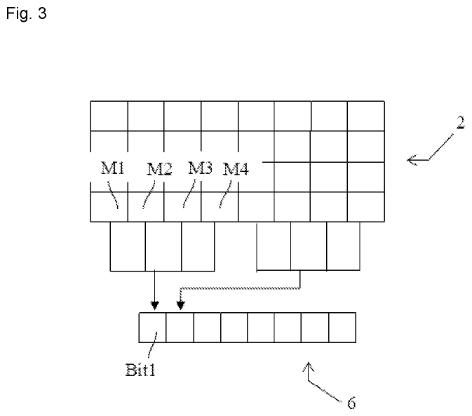

When the size of the memory is very large, a bit can be associated with several words of the memory so as to reduce the number of bits of the register. The time to read the register is also reduced by this same factor. If G is used to denote the set of words associated with one and the same bit then the number NBR can be reduced by this factor G and there is the simple relationship: NBR=T/G. FIG. 3 illustrates this principle. The memory 2 comprises 32 words and the register 6 comprises 8 bits. Groups of four words therefore address the same bit as can be seen in this FIG. 3. Thus, the first words M1, M2, M3 and M4 are associated with bit 1 and so on.

The size of a group is generally a power of 2. It should be noted that it is not necessary for the size of the memory to be itself a power of 2.

The operation of the electronic system is cyclical. The duration of the cycle depends on the technology and on the size of the memory 2, on the desired accuracy, on the flight altitude of the aircraft which carries the embedded system comprising said memory.

At the start of a cycle or at the end of a cycle, the processor 3 commands the resetting of the register 6 by means of the reset command 5.

Next, each time, for the duration of the cycle, a word of the memory 2 is used, it is also scanned by the error estimator 4. If the estimator does not observe any error, then the bit of the register corresponding to said word of the memory remains at 0.

If the error estimator observes an error on this word, then the bit of the register changes to 1 if it was at 0. If the bit was already at 1, then it remains at 1. It has been seen that the size of the register can be either equal to the size of the memory or be a submultiple. When the size of the register is equal to the memory size, the retention of the bit of the register at 1 means that, when a word of the memory comprising an error is read several times, the error estimator is prevented from indexing it several times in the register.

When the size of the register is a submultiple of the size of the memory, that means that a group of words associated with a register bit is counted only once, even if several different words of this group include errors. This arrangement results in a simple reduction of the resolution, which corresponds to the fact that the size of the register is smaller than the size of the memory.

When the duration of the cycle has elapsed, all of the register is read by the electronic processor for subsequent processing, either for statistical purposes, or for memory management purposes. Obviously, it is possible to process a plurality of memories simultaneously.

The internal geometry of the memories is rarely known for reasons related to industrial secrecy concerning the layout of the memories, and the relationship which exists between the addresses of the words and the geometrical position of the words on the chip which carries the memory is therefore not known. In this case, the groups can be chosen arbitrarily. For example, it is possible, to simplify the reading, to choose groups of words whose addresses are contiguous.

If the physical location of the words within the chip is known, it is advantageous to choose, for each group, words which are not physically contiguous. If the geometry of the memory is made in such a way that two contiguous addresses are not stored at the same physical location, a first simple solution consists in choosing groups of words with contiguous addresses as previously.

If the contiguous addresses physically follow one another on the memory, a second solution consists in spreading each group over all the memory by grouping together words spaced apart by G words. For example, the first group will contain the G words with address numbers 0, (G−1), (2G−1), (3G−1) and so on, the second group will contain the G words with address numbers 1, G, 2G, 3G, and so on, the third group will contain the G words with address numbers 2, (G+1), (2G+1), (3G+1) and so on.

In a variant embodiment, the spreading can advantageously be done by subgroups instead of being done word by word.

This grouping together is advantageous when the current application uses only a part of the memory. Generally, in such a case, only the low part of the memory is used and the above grouping together enhances granularity.

For example, if only the bottom half of the memory, which corresponds to the addresses numbered from 0 to T/2−1, is used, by using a contiguous grouping, only the first groups are invoked. In effect, the second half of the groups is associated with memory words which are never read. The granularity is then equal to G.

With the spread grouping, all the groups are invoked because they all contain words in the bottom part of the memory. Furthermore, it is precisely half of the words of each group which is invoked, and the other half of the words of the groups is never invoked. From the counting point of view, everything takes place as if the groups were two times smaller. The granularity is then G/2. There is thus a saving by a factor of 2 with respect to the preceding case.

As has been stated, it is advantageous for the size G of the groups to be a power of 2. In fact, in this case, the coding of the addresses, which is done in binary, is simplified.

The advantages of the detection device according to the invention are as follows. For an application, it processes all of the words of the memory necessary to that application and only that.

Whatever the size of the register which counts the alterations, they are counted only once, even if the affected word is read several times during the application. Interpretation errors concerning damage caused to the memory are thus avoided.

The device does not alter the performance of the electronic system which comprises the memory and in particular the memory access times. Finally, it requires only minor adaptations to the electronic system which are very easy to implement.

1. An electronic system for aeronautical applications comprising at least one electronic memory comprising a first plurality (T) of words, an error detection system, wherein the electronic system comprises an error counting device comprising:
a register comprising a second plurality (NBR) of bits, an address of a bit being associated with at least one word;
means for indexing the bit associated with said word when the error detection system flags an alteration of said word, the indexation of said bit being unique within a given time period, regardless of the number of times the alteration of said word is detected by the error detection system in said given time period;
means for resetting the register at the end of the given time period.

2. The electronic system according to claim 1, wherein the second plurality is equal to the first plurality, the number of bits of the register being strictly equal to the number of words of the memory, each address corresponding to a single word.

3. The electronic system according to claim 1, wherein the second plurality is a submultiple of the first plurality, the words being divided up by groups (G) of the same size, each group of words being associated with a unique bit address.

4. The electronic system according to claim 3, wherein the different words of one and the same group associated with a unique bit address have address numbers which follow one another.

5. The electronic system according to claim 3, wherein the different words of one and the same group associated with a unique bit address are chosen so as to be separated physically in the electronic memory.
